(19) United States
(12) Patent Application Publication
(10) Pub. No.: US 2015/0188011 A1
(43) Pub. Date: Jul. 2, 2015

(54) SIDE-EMITTING TYPE NITRIDE SEMICONDUCTOR LIGHT EMITTING CHIP AND NITRIDE SEMICONDUCTOR LIGHT EMITTING DEVICE HAVING THE SAME

(71) Applicant: ILJIN LED CO., LTD., Ansan-si (KR)

(72) Inventor: Pil-Geun KANG, Ansan-si (KR)

(21) Appl. No.: 14/584,361

(22) Filed: Dec. 29, 2014

(30) Foreign Application Priority Data
Dec. 30, 2013 (KR) 10-2013-0167544

(51) Int. Cl. H01L 33/60; H01L 33/56; H01L 33/50; H01L 33/42; H01L 33/62

(52) U.S. Cl. CPC H01L 33/60; H01L 33/42; H01L 33/62; H01L 33/50; H01L 33/56

(57) ABSTRACT

Disclosed are a side-emitting type nitride semiconductor light-emitting chip and a light-emitting device comprising the same, which emit light from the sides so that the beam angle of the light can be increased and the need for a lead frame mold cup and a lens can be eliminated.

### CROSS-REFERENCE TO RELATED APPLICATION

This application claims the benefit under 35 U.S.C. §119 of Korean Patent Application No. 10-2013-0167544 filed on Dec. 30, 2013 in the Korean Intellectual Property Office, the entirety of which disclosure is incorporated herein by reference.

### BACKGROUND

1. Technical Field

The present invention relates to a nitride semiconductor light-emitting chip, and more particularly, to a side-emitting type nitride semiconductor light-emitting chip and a light-emitting device including the same, which are designed to emit light from the sides so that the beam angle of the light can be increased and the need for a lead frame mold cup and a lens can be eliminated.

2. Related Art

In recent years, among nitride semiconductor light-emitting devices, GaN-based nitride semiconductor light-emitting devices have been mainly studied. Such GaN-based nitride semiconductor light-emitting devices have been applied to blue and green light-emitting devices (LEDs), high-speed switching and high-power devices such as MESFETs and HEMTs, and the like.

In particular, blue and green light-emitting devices are already in a mass production stage.

FIG. 1 is a cross-sectional view showing a conventional nitride semiconductor light-emitting device.

Referring to FIG. 1, a conventional nitride semiconductor light-emitting device 1 includes: a lead frame 10 having terminals 12; a light-emitting diode 20 mounted on the lead frame 10; metal wires 60 that electrically connect the terminals 12 of the lead frame 10 to the light-emitting diode 20; a lead frame mold cup 30 having a window that exposes the light-emitting diode 20; a reflective layer 50 formed on the sidewall of the lead frame mold cup 30; an epoxy resin layer 40 filled in the lead frame mold cup 30; and a lens 70 attached to the epoxy resin layer 40.

The conventional nitride semiconductor light-emitting device 1 having this configuration has a shortcoming in that the design of the lead frame mold cup 30 and the reflective layer 50 can necessarily narrow the beam angle of light.

Particularly, when the nitride semiconductor light-emitting device 1 is to be mounted on the cover bottom of a direct-type LED TV, the lens 70 is attached to the epoxy resin layer 40 to increase the beam angle to 120° so that the lights emitted from the light-emitting diode 20 will be easily mixed. When this lens 70 is attached, process failure frequently occurs due to misalignment. In addition, the attachment of the lens 70 leads not only to an increase in the thickness of the conventional nitride semiconductor light-emitting device 1, but also to an increase in a direct-type LED TV, thus making it difficult to satisfy light, thin, short and small requirements.

Related prior art documents include Korean Patent No. 10-1078032 (published on Oct. 24, 2011), which discloses a side-emitting type light-emitting device package and a backlight module including the same.

### SUMMARY

Various embodiments are directed to a side-emitting type nitride semiconductor light-emitting chip and a light-emitting device including the same, which are fabricated by mounting a flip-type light-emitting diode on a package substrate and connecting the light-emitting diode and the package substrate directly to external electrode terminals so as to provide a high power device to which a high current can be applied, and which are designed to emit light from the sides so that the beam angle of the light can be increased to about 180°.

In an embodiment, a side-emitting type nitride semiconductor light-emitting chip includes: a light-emitting diode; a molding that covers the light-emitting diode; and a reflective plate formed on the molding and configured to reflect light, incident from the light-emitting diode, to the side of the chip.

In another embodiment, a side-emitting type nitride semiconductor light-emitting device includes: a light emitting chip including a light-emitting diode, a molding that covers the light-emitting diode, and a reflective plate formed on the molding and configured to reflect light, incident from the light-emitting diode, to the side of the chip; a package substrate that supports the light-emitting chip; and external electrode terminals formed in the package substrate and configured to apply an electrical signal to the light-emitting diode.

### BRIEF DESCRIPTION OF THE DRAWINGS

FIG. 1 is a cross-sectional view showing a conventional nitride semiconductor light-emitting device.

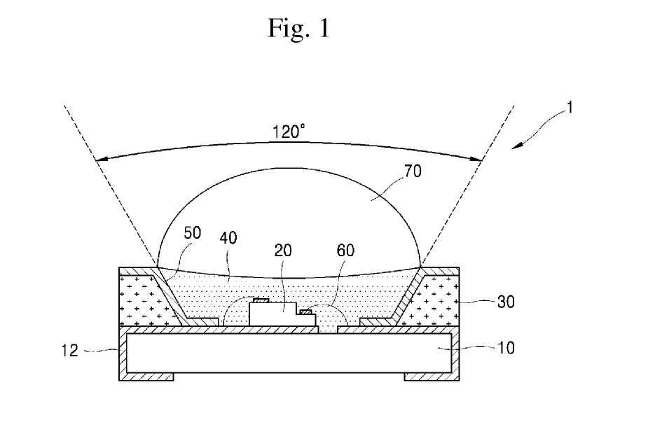

FIG. 2 is a cross-sectional view showing a side-emitting type nitride semiconductor light-emitting device according to an embodiment of the present invention.

FIG. 3 is an enlarged view of portion “A” shown in FIG. 2.

FIG. 4 is a cross-sectional view showing the light-emitting diode of FIG. 3 in further detail.

FIG. 5 illustrates the principle of light emission from a side-emitting type nitride semiconductor light-emitting device according to an embodiment of the present invention.

FIG. 6 illustrates an example of application of a side-emitting type nitride semiconductor light-emitting device according to an embodiment of the present invention.

### DETAILED DESCRIPTION

Exemplary embodiments will be described below in more detail with reference to the accompanying drawings. The disclosure may, however, be embodied in different forms and should not be constructed as limited to the embodiments set forth herein. Rather, these embodiments are provided so that this disclosure will be thorough and complete, and will fully convey the scope of the disclosure to those skilled in the art. Throughout the disclosure, like reference numerals refer to like parts throughout the various figures and embodiments of the disclosure.

Hereinafter, a side-emitting type nitride semiconductor light-emitting chip according to exemplary embodiments of the present invention and a light-emitting device including the same will be described with the accompanying drawings.

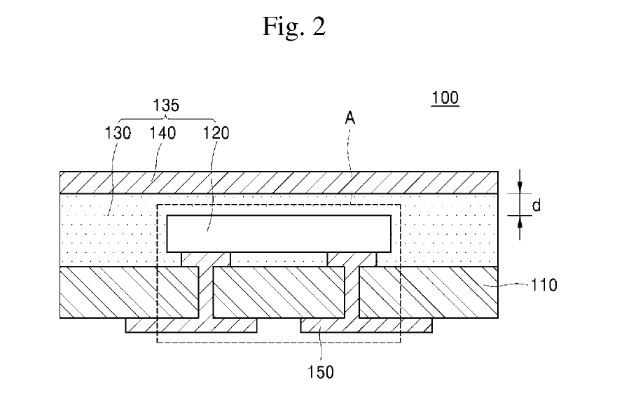

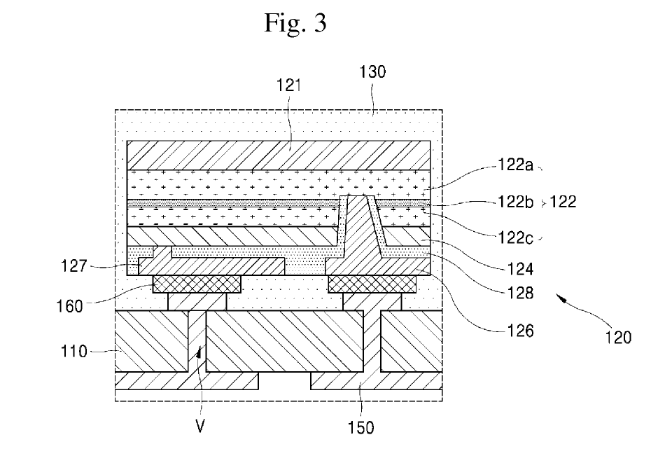

FIG. 2 is a cross-sectional view showing a side-emitting type nitride semiconductor light-emitting device according to an embodiment of the present invention, and FIG. 3 is an enlarged view of the portion A shown in FIG. 2.

Referring to FIGS. 2 and 3, a side-emitting type nitride semiconductor light-emitting device 100 according to an embodiment of the present invention includes a package substrate 110, a light-emitting chip 135, and external electrode terminals 150.

The package substrate 110 has an upper surface and a lower surface, and includes via holes (V) that pass through the upper and lower surfaces. Such via holes (V) may be formed to pass through the central portion of the package substrate 110, but is not limited thereto, and may be disposed at the edges of the package substrate 110. Herein, the package substrate 110 may be any one selected from among a printed circuit board (PCB), a lead frame, a ceramic substrate, a metal substrate and the like.

The light-emitting chip 135 includes a light-emitting diode 120, a molding 130 and a reflective plate 140.

The light-emitting diode 120 is attached to the upper surface of the package substrate 110. Herein, the light-emitting diode 120 is preferably attached in a flip-chip form, but is not limited thereto, and may also be attached in the form of a lateral type chip or a vertical type chip. This light-emitting diode 120 may include a light-emitting structure 122, a reflective layer 124, a first bonding pad 126, a second bonding pad, and an insulating layer 128, but is not limited to this configuration.

The molding 130 covers the upper surface of the package substrate 110 and the entire surface of the light-emitting diode 120. Herein, the molding 130 may be formed to cover and seal the upper surface of the package substrate 110 and the entire surface of the light-emitting diode 120. Alternatively, the molding 130 may be formed so as to expose only a portion of the external electrode terminals 150 disposed on the upper surface of the package substrate 110 and to seal the upper surface of the package substrate 110, which excludes the exposed portion, and the entire surface of the light-emitting diode 120.

This molding 130 may be made of pure epoxy resin, and in this case, red (R), green (G) or blue (B) can be generated depending on the color of light emitted from the light-emitting diode 120.

Specifically, the molding 130 may include one or more selected from among epoxy resin, silicone resin and polyimide resin. Alternatively, the molding 130 may be made of a mixture of a wavelength conversion material and one or more selected from among epoxy resin, silicone resin and polyimide resin. Alternatively, the molding 130 may include a resin layer formed of one or more selected from among epoxy resin, silicone resin and polyimide resin, and a wavelength conversion film attached to the resin layer and serving to convert light having a specific wavelength to light having other wavelength.

Herein, the molding 130 is preferably formed to have an area corresponding to that of the package substrate 110 such that the ends thereof are in line with the sides of the package substrate 110. This molding 130 may be formed as thin as 50-2000 μm. This is because light is not emitted from the top, but is emitted from the sides, and thus it is possible to ensure the beam angle of the light even when the vertical thickness is reduced.

If the thickness of the molding 130 is less than 50 μm, it will be difficult to securely protect the light-emitting diode 120. On the other hand, if the thickness of the molding 130 is more than 2000 μm, an increase in the thickness will not lead to a further increase in the effect of the molding 130.

The reflective plate 140 is formed on the molding 130, and functions to reflect light, incident vertically from the light-emitting diode 120, to the sides. This reflective plate 140 may be disposed on the front side of the molding 130, but is not limited thereto.

Herein, the reflective plate 140 preferably has a thickness of 0.1-1000 μm, and more preferably 50-500 μm. If the thickness of the reflective plate 140 is less than 0.1 μm, the reflective plate 140 will not sufficiently exhibit its function. On the other hand, if the thickness of the reflective plate 140 is more than 1000 μm, an increase in the thickness will increase the fabrication cost without further increasing the effect, and will lead to a result contrary to the current trend toward thin, small, short and small characteristics. Meanwhile, when the thickness of the reflective plate 140 is maintained at 50-500 μm, scattered reflection that can be caused by an increase in the surface roughness due to an increase in the thickness can be reduced, resulting in an increase in the reflectivity, and the fabrication cost can be reduced due to a decrease in the thickness.

This reflective plate 140 may be made of at least one material selected from among titanium (Ti), silicon (Si), zinc (Zn), niobium (Nb), tungsten (W), tin (Sn), zirconium (Zr), strontium (Sr), tantalum (Ta), nickel (Ni), cadmium (Cd), silver (Ag), aluminum (Al), palladium (Pd), ruthenium (Ru), platinum (Pt), rhodium (Rh), and compounds, mixtures, oxides and sulfides thereof.

The external electrode terminals 150 are formed in the package substrate 110, and function to apply an electrical signal to the light-emitting diode 120. One end of each of such external electrode terminals 150 is electrically connected to each of the first binding pad 126 and second bonding pad 127 of the light-emitting diode 120, and the other end extends to the lower surface of the package substrate 110. The external electrode terminals 150 may be formed so as to be filled in via holes (V) passing through the package substrate 110, but are not limited thereto. Alternatively, the external electrode terminals 150 may also be formed on the package substrate 110 without a via hole.

After the light-emitting diode 120 was attached to the package substrate 110, the first bonding pad 126 and second bonding pad 127 of the light-emitting diode 120 are electrically connected to the external electrode terminals 150, respectively, by eutectic bonding or soldering. When this eutectic bonding or solder bonding is used, the electrical connection path is shortened to reduce electrical resistance, and the heat dissipation path is shortened, compared to a conventional process that uses metal wires. Thus, it is possible to fabricate a high-power device to which a high current can be applied.

When soldering is used, the first and second bonding pads are electrically connected to the external electrode terminals by a bump composed of an alloy of two or more elements selected from among Cr, Ti, Pt, Au, Mo and Sn, for example, Au/Sn, Pt/Au/Sn, Cr/Au/Sn, or the like.

Particularly, the bump 160 is preferably a metal layer including one or more selected from among Au and Sn. Meanwhile, for eutectic bonding, an alloy including Sn, Ag, Cu or the like may be used. Particularly, an AuSn alloy, a NiSn alloy or an AgSn alloy is preferably used.

Accordingly, the first and second bonding pads 126 and 127 in the present invention can be bonded not only by soldering, but also by eutectic bonding, and thus the light-emitting diode can be mounted by any one selected from among the two bonding processes.

Although not shown in the drawings in detail, each of the external electrode terminals 150 may have a stacked structure and may include a metal layer (not shown) made of one or more selected from among copper (Cu), nickel (Ni), chromium (Cr), molybdenum (Mo), tungsten (W) and the like, and a surface treatment layer (not shown) formed on the metal layer by plating or surface-treating one or more of tin (Sn), silver (Ag) and OSP (organic solderability preservative).

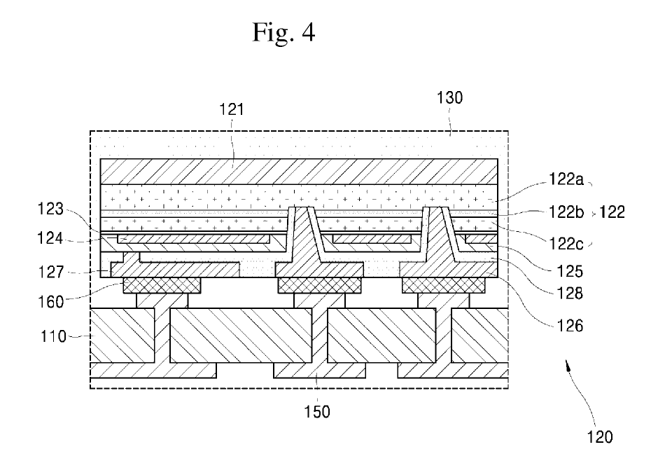

Hereinafter, the light-emitting diode will be described in further detail with reference to FIG. 4 that shows the light-emitting diode of FIG. 3 in further detail.

As shown in FIG. 4, the light-emitting diode 120 according to the present invention includes a light-emitting structure 122, a transparent conductive layer 123, a reflective layer 124, a first metal diffusion barrier layer 125, a first bonding pad 126, and a second bonding pad 127. In addition, the light-emitting diode 120 may further include an insulating layer 128.

The light-emitting structure 122 has a first conductivity type nitride layer 122a, an active layer 122b and a second conductivity type nitride layer 122c, which are sequentially deposited over a substrate 121.

The first conductivity type nitride layer 122a is formed on the substrate 121. This first conductivity type nitride layer 122a may have a structure formed by alternately depositing a first layer (not shown), made of silicon (Si)-doped AlGaN, and a second layer (not shown) made of undoped-GaN. Of course, the first conductivity type nitride layer 122a may also consist of a single nitride layer. However, it is preferably formed to have a multilayer structure, because a structure formed by alternately depositing the first layer (including a buffer layer (not shown)) and the second layer can exhibit excellent crystallinity without cracking.

The substrate 121 may be formed of a material suitable for growing a nitride semiconductor single-crystal, and a representative example thereof may be a sapphire substrate. In addition to the sapphire substrate, the substrate 121 may also be formed of a material selected from among zinc oxide (ZnO), gallium nitride (GaN), silicon (Si), silicon carbide (SiC), aluminum nitride (AlN), and the like. Although not shown in the drawings, the light-emitting diode 120 may further include a buffer layer interposed between the substrate and the first conductivity type nitride layer 122a. Herein, the buffer layer is optionally provided on the upper surface of the substrate 121, and is formed in order to overcome the lattice mismatch between the substrate 121 and the first conductivity type nitride layer 122a. It may be made of a material selected from among AlN, GaN and the like.

The active layer 122b is formed on the first conductivity type nitride layer 122a. This active layer 122b is disposed between the first conductivity type nitride layer 122a and the second conductivity type nitride layer 122c, and may have a single quantum well structure or a multi-quantum well (MQW) structure formed by alternately depositing a quantum well layer and a quantum barrier layer several times. Specifically, the active layer 122b has a multi-quantum well structure including quantum barrier layers, composed of an Al-containing quaternary nitride layer of AlGaInN, and quantum well layers formed of InGaN. The active layer 122b having this multi-quantum well structure can suppress the spontaneous polarization caused by stress and deformation.

The second conductivity type nitride layer 122c may have, for example, a structure formed by alternately depositing a first layer (not shown), formed of p-type AlGaN doped with Mg as a p-type dopant, and a second layer (not shown) formed of p-type GaN doped with Mg. In addition, the second conductivity type nitride layer 122c may act as a carrier restriction layer, like the first conductivity type nitride layer 122a.

The transparent conductive layer 123 is formed on the light-emitting structure 122. This transparent conductive layer 123 is made of a transparent conductive material, and may include a metal. For example, it may be a combination of s nickel (Ni) layer and a gold (Au) layer. In addition, the transparent conductive layer 123 may include an oxide. For example, it may be a layer made of at least one selected from among ITO (indium tin oxide), IZO (indium zinc oxide), IZTO (indium zinc tin oxide), AZO (aluminum zinc oxide), IAZO (indium aluminum zinc oxide), GZO (gallium zinc oxide), IGO (indium gallium oxide), IGZO (indium gallium zinc oxide), IGTO (indium gallium tin oxide), ATO (aluminum tin oxide), IWO (indium tungsten oxide), CIO (copper indium oxide), MIO (magnesium indium oxide), MgO, ZnO, In₂O₃, TiTaO₂, TiNbO₂, TiOx, RuOx, IrOx, and combinations thereof.

The reflective layer 124 is formed on the transparent conductive layer 123. The reflective layer 124 is made of a metal having high light reflectivity. Specifically, it may be made of at least one selected from among Ag, Al, Au, Ni, Pd, Pt, Ru, Rh, and alloys and combinations thereof. More specifically, the reflective layer 124 may include a light reflective layer (not shown) and a metal oxidation preventing layer (not shown). Specifically, the reflective layer 124 is preferably composed of a multi-layer metal layer formed by sequentially depositing a light reflective layer made of Ag and a metal oxidation preventing layer made of Ni. This reflective layer 124 may preferably have a thickness of 500-5000 Å, and more preferably 1500-3500 Å.

For a flip-type light-emitting diode, the reflective layer 124 is mainly made of highly reflective Ag. In the present invention, the transparent conductive layer 123 is interposed between the second conductivity type nitride layer 122c and the reflective layer 124 in order to increase the adhesion between the reflective layer 124 and the second conductivity type nitride layer 122c. When the transparent conductive layer 123 is interposed between the second conductivity type nitride layer 122c and the reflective layer 123 as described above, the transparent conductive layer 123 can be securely attached to the second conductivity type nitride layer 122c, and thus can enhance the forward voltage (Vf) and optical power (PO) characteristics.

The first metal diffusion barrier layer 125 is formed on the reflective layer 124. This first metal diffusion barrier layer 125 is preferably a multi-layer metal layer including at least one selected from among Cr, Ni, Pt, Ti, Au, Cu, W, and compounds thereof.

This first metal diffusion barrier layer 125 functions to prevent the characteristics of the reflective layer 124, particularly reflectivity and contact resistance, from being reduced due to the fusion and combination of materials at the interface between the reflective layer 124 and the first and second bonding pads 126 and 127.

Although not shown in the drawings, the first metal diffusion barrier layer 125 may further include a first adhesive metal layer (not shown) formed on each of the top and bottom surfaces thereof. This first adhesive metal layer is preferably composed of a metal layer including Cr or Ti. Herein, the first adhesive metal layer disposed on the top surface of the first metal diffusion barrier layer 125 is formed for the purpose of increasing the adhesion between the first metal diffusion barrier layer 125 and the reflective layer 124, and the first adhesive metal layer disposed on the bottom surface of the first metal diffusion barrier layer 125 is formed for the purpose of increasing the adhesion between the first metal diffusion barrier layer 125 and the first and second bonding pads 126 and 127.

The first bonding pad 126 is formed on the first conductivity type nitride layer 122a, and the second bonding pad 127 is formed on the second conductivity type nitride layer 122c of the light-emitting structure. Herein, the first bonding pad 126 and the second bonding pad 127 can be formed by any one process selected from among E-beam evaporation, thermal evaporation, sputtering deposition, and the like. The first bonding pad 126 and the second bonding pad 127 may be formed from the same material using the same mask. Herein, the first bonding pad 126 and the second bonding pad 127 may be formed of a material selected from among Au, a Cr—Au alloy, etc.

Although not shown in the drawings, each of the first and second bonding pads 126 and 127 may include an upper adhesive metal layer (not shown), a second metal diffusion barrier layer (not shown) and a lower adhesive metal layer. Herein, each of the upper adhesive metal layer and the lower adhesive metal layer is preferably composed of a metal layer including Ti or Au. The upper adhesive metal layer is formed for the purpose of increasing the adhesion between the first and second bonding pads 126 and 127 and the first metal diffusion barrier layer 125, and the lower adhesive metal layer is formed for the purpose of increasing the adhesion between the first and second bonding pads 126 and 127 and the bumps 160 or the external electrode terminals 150.

The second metal diffusion barrier layer is preferably composed of a multi-layer metal layer including at least one selected from among Cr, Ni, Pt, Ti, Au, Cu, W, and compounds thereof, in order to prevent contact resistance from being reduced due to the fusion and combination of materials at the interface between the first and second bonding pads 126 and 127 and the first metal diffusion barrier layer 125.

The insulating layer 128 functions to electrically insulate the first bonding pad 126 and the second bonding pad 127 from each other. The insulating layer 128 may be made of at least one selected from among compounds and mixtures, which contain Si, Mg, Ti, Al, Zn, C, In or Sn, or may be made of at least one selected from among oxides, fluorides, sulfides and nitrides of these elements. In addition, it may have a multilayer structure so that it can be used as any one of a DBR (Distributed Bragg Reflector) layer or an ODR (Omni Directional Reflector) layer. If it is used as the DBR layer, it is composed of a plurality of layers having different reflective indices. The DBR layer may be made of any one selected from among compounds, mixtures, oxides and nitrides, which contain Si, Ti, Ta, V, Cr, Mg, Al, Zn, In, Sn or C, or may be made of any one selected from among fluorides, sulfides and nitrides of these elements. Among them, any one of the above-described oxides, nitrides and fluorides is more preferably used. The thickness of the DBR layer is preferably 10-900 Å, and the number of deposition cycles of the DBR layer is not limited, but is preferably 20 cycles (k=20) or less.

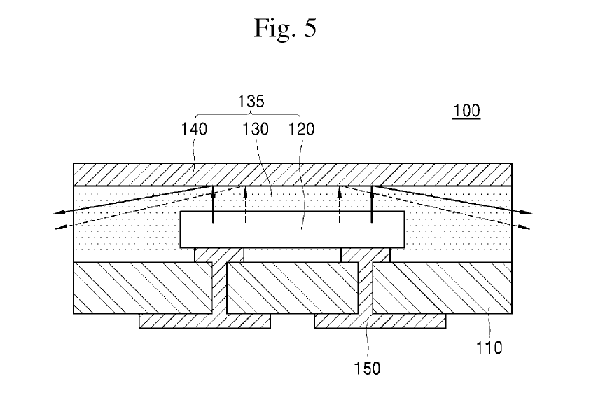

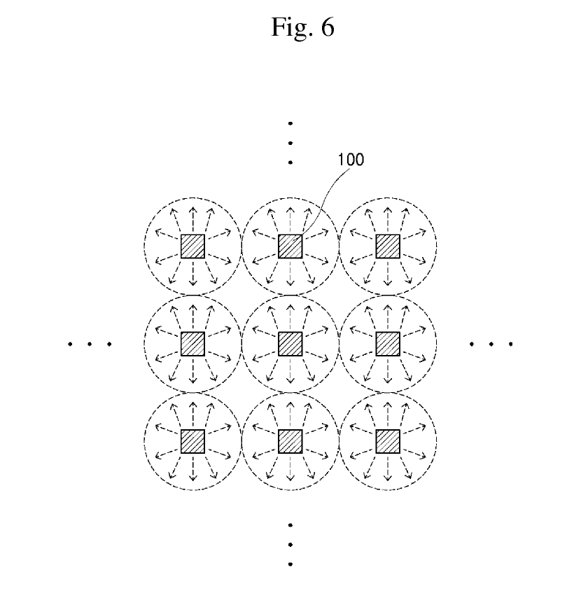

Meanwhile, FIG. 5 illustrates the principle of light emission from a side-emitting type nitride semiconductor light-emitting device according to an embodiment of the present invention, and FIG. 6 illustrates an example of application of a side-emitting type nitride semiconductor light-emitting device according to an embodiment of the present invention.

As shown in FIG. 5, in the case of a side-emitting type nitride semiconductor light-emitting device 100 according to an embodiment of the present invention, light is emitted from the light-emitting diode 120 and incident vertically through the molding 130. The incident light is reflected by the reflective plate 140 and emitted from the sides of the package substrate 110 and the molding 130.

As shown in FIG. 6, when a plurality of side-emitting type nitride semiconductor light-emitting devices 100 are applied to a direct-type LED TV, they can be arranged in a matrix configuration on the cover bottom of the direct-type LED TV.

In the case of the plurality of side-emitting type nitride semiconductor light-emitting devices 100, light is emitted from the sides of each of the side-emitting type nitride semiconductor light-emitting devices 100 located adjacent to one another, and the emitted from the sides are mixed with one another while they are emitted vertically. Thus, the beam angle of light can be increased to about 180°. As a result, the side-emitting type nitride semiconductor light-emitting device 100 according to the present invention emits light from the sides, and thus the beam angle of the light can be increased to about 180° without needing to use a separate lens.

As described above, according to the embodiment of the present invention, the side-emitting type nitride semiconductor light-emitting chip and the light-emitting device including the same are fabricated by mounting the flip-type light-emitting diode on the package substrate and connecting the light-emitting diode and the package substrate directly to the external electrode terminals by eutectic bonding or soldering, so as to provide a high power device to which a high current can be applied. In addition, because the light-emitting chip and device are designed to emit light from the sides, and thus the beam angle of the light can be increased to about 180°.

Also, the side-emitting type nitride semiconductor light-emitting chip according to the embodiment of the present invention and the light-emitting device including the same do not require a lead frame mold cup and a lens, and thus the fabrication cost thereof is reduced, and the light-emitting device has a light, thin, short and small configuration due to a decrease in the overall thickness of the package.

In addition, the side-emitting type nitride semiconductor light-emitting chip according to the embodiment of the present invention and the light-emitting device including the same do not require a lens, and thus have a light, thin, short and small configuration. Thus, when the light-emitting device is mounted in a direct-type LED TV, the TV can have reduced thickness, volume and weight. For this reason, distribution costs can be reduced, leading to a reduction in the expenses of manufacturers.

While various embodiments have been described above, it will be understood to those skilled in the art that the embodiments described are by way of example only. Accordingly, the disclosure described herein should not be limited based on the described embodiments.

What is claimed is:

1. A side-emitting type nitride semiconductor light-emitting chip, comprising:
a light-emitting diode;
a molding that covers the light-emitting diode; and
a reflective plate formed on the molding and configured to reflect light, incident from the light-emitting diode, to sides of the chip.

2. The side-emitting type nitride semiconductor light-emitting chip of claim 1, wherein the light-emitting diode comprises:
a light-emitting structure formed over a substrate and having a first conductivity type nitride layer, an active layer and a second conductivity type nitride layer;
a transparent conductive layer formed on the light-emitting structure;
a reflective layer formed on the transparent conductive layer;
a first metal diffusion barrier layer formed on the reflective layer;
a first bonding pad electrically connected with the first conductivity type nitride layer; and
a second bonding pad electrically connected with the second conductivity type nitride layer.

3. The side-emitting type nitride semiconductor light-emitting chip of claim 2, wherein the reflective layer comprises a light reflective layer and a metal oxidation preventing layer.

4. The side-emitting type nitride semiconductor light-emitting chip of claim 2, wherein the reflective layer is a single-layered or multi-layered metal layer comprising at least one selected from among Ag, Al, Au, Ni, Pd, Pt, Ru and Rh.

5. The side-emitting type nitride semiconductor light-emitting chip of claim 2, wherein the first metal diffusion barrier layer is a single-layer or multi-layer metal layer comprising at least one selected from among Cr, Ni, Pt, Ti, Au, Cu and W.

6. The side-emitting type nitride semiconductor light-emitting chip of claim 2, wherein each of the first and second bonding pads comprises an upper adhesive metal layer, a second metal diffusion barrier layer and a lower adhesive metal layer.

7. The side-emitting type nitride semiconductor light-emitting chip of claim 6, wherein the second metal diffusion barrier layer is a single-layer or multi-layer metal layer comprising at least one selected from among Cr, Ni, Pt, Ti, Au, Cu and W.

8. The side-emitting type nitride semiconductor light-emitting chip of claim 2, wherein the light-emitting diode further comprises an insulating layer formed on the first metal diffusion barrier layer.

9. The side-emitting type nitride semiconductor light-emitting chip of claim 1, wherein the molding comprises one or more selected from among epoxy resin, silicone resin and polyimide resin.

10. The side-emitting type nitride semiconductor light-emitting chip of claim 1, wherein the molding comprises: a wavelength conversion material; and one or more selected from among epoxy resin, silicone resin and polyimide resin.

11. The side-emitting type nitride semiconductor light-emitting chip of claim 1, wherein the molding comprises: a resin layer formed of one or more selected from among epoxy resin, silicone resin and polyimide resin; and a wavelength conversion film attached to the resin layer and configured to convert light having a specific wavelength to light having other wavelength.

12. The side-emitting type nitride semiconductor light-emitting chip of claim 1, wherein the molding has a thickness of 50-2000 μm.

13. The side-emitting type nitride semiconductor light-emitting chip of claim 1, wherein the reflective plate has a thickness of 0.1-1000 μm.

14. The side-emitting type nitride semiconductor light-emitting chip of claim 1, wherein the reflective plate comprises at least one selected from among titanium (Ti), silicon (Si), zinc (Zn), niobium (Nb), tungsten (W), tin (Sn), zirconium (Zr), strontium (Sr), tantalum (Ta), nickel (Ni), cadmium (Cd), silver (Ag), aluminum (Al), palladium (Pd), ruthenium (Ru), platinum (Pt) and rhodium (Rh).

15. A side-emitting type nitride semiconductor light-emitting device comprising:
a light emitting chip comprising a light-emitting diode, a molding that covers the light-emitting diode, and a reflective plate formed on the molding and configured to reflect light, incident from the light-emitting diode, to sides of the chip;
a package substrate that supports the light-emitting chip; and
external electrode terminals formed in the package substrate and configured to apply an electrical signal to the light-emitting diode.

16. The side-emitting type nitride semiconductor light-emitting device of claim 15, wherein one end of each of the external electrode terminals is electrically connected to each of the first bonding pad and the second bonding pad, and the other end extends to a lower surface of the package substrate.

17. The side-emitting type nitride semiconductor light-emitting device of claim 15, wherein the package substrate is any one of a printed circuit board (PCB), a lead frame, a ceramic substrate and a metal substrate.

18. The side-emitting type nitride semiconductor light-emitting device of claim 15, wherein the molding is formed to have an area corresponding to that of the package substrate such that ends thereof are in line with sides of the package substrate.

19. The side-emitting type nitride semiconductor light-emitting device of claim 15, wherein each of the external electrode terminals has a stacked structure and comprises:
a metal layer comprising one or more of copper (Cu), nickel (Ni), chromium (Cr), molybdenum (Mo) and tungsten (W); and
a surface treatment layer formed on the metal layer by plating or surface-treating one or more of tin (Sn), silver (Ag) and OSP (organic solderability preservative).
